(19) United States
(12) Patent Application Publication
(10) Pub. No.: US 2019/0088545 A1
(43) Pub. Date: Mar. 21, 2019

(54) MANUFACTURING METHOD OF SEMICONDUCTOR DEVICE

(71) Applicant: TOSHIBA MEMORY CORPORATION, Minato-ku (JP)

(72) Inventor: Shinya OKUDA, Yokkaichi (JP)

(73) Assignee: TOSHIBA MEMORY CORPORATION, Minato-ku (JP)

(21) Appl. No.: 15/915,093

(22) Filed: Mar. 8, 2018

(30) Foreign Application Priority Data
Sep. 21, 2017 (JP) 2017-181435

(51) Int. Cl. H01L 21/768; H01L 21/02; H01L 23/48

(52) U.S. Cl. CPC H01L 21/76898; H01L 21/76831; H01L 21/76841; H01L 27/115; H01L 21/02274; H01L 23/481; H01L 21/02164

(57) ABSTRACT

In a manufacturing method of a semiconductor device according to the present embodiment, a semiconductor substrate, which has a first face and a second face, is bonded to a support substrate with the first face facing toward the support substrate. The first face has a semiconductor element. The second face is located opposite to the first face. The semiconductor substrate is processed from the second face to form a contact hole to reach the first face from the second face. A first insulation film is formed on an inner surface of the contact hole. A metal is embedded on the first insulation film in the contact hole to form a metal electrode. The formation of the first insulation film is performed by plasma CVD in an atmosphere of 200° C. or lower, containing a gas containing silicon and oxygen, an oxygen-containing gas, and an NH-group containing gas.

### CROSS REFERENCE TO RELATED APPLICATIONS

This application is based upon and claims the benefit of priority from the prior Japanese Patent Application No. 2017-181435, filed on Sep. 21, 2017, the entire contents of which are incorporated herein by reference.

### FIELD

Embodiments relate to a manufacturing method of a semiconductor device.

### BACKGROUND

Semiconductor chips of semiconductor memories and the like are layered one another as required on the point of view of high functionality, high integration, etc. Through electrodes referred to as TSVs (Through-Silicon Vias) are used for electrically connecting elements of a plurality of layered semiconductor chips, one another. The TSVs penetrate through a semiconductor substrate to be electrically connected to elements of another semiconductor chip.

In order to electrically isolate the TSVs against the substrate, a spacer layer is formed on the inner surface of a contact hole for use in TSV. However, the contact hole for use in TSV has a high aspect ratio. Plasma CVD with TEOS is used for forming the spacer layer with excellent coverage up to the bottom of such a contact hole having a high aspect ratio. This is because, a spacer layer formed by plasma CVD with TEOC is excellent in coverage than that formed by plasma CVD with silane.

In the case of a via-last process to form a TSV after forming a semiconductor element on a semiconductor substrate, the TSV is formed after that an element forming surface of the semiconductor substrate is fixed on a support substrate with an adhesive and then the semiconductor substrate is thinned by polishing the rear face of the semiconductor substrate. In this case, in order for the adhesive not to be melted, the TSV formation is performed, for example, at a low temperature of 200° or lower.

When plasma CVD using TEOS is performed, for example, at a low temperature, a lot of OH groups (moisture) are contaminated into the spacer layer. The OH groups as moisture may cause a leakage current between the TSV and the substrate, or may evaporate to cause cracks or peeing-off of an interlayer insulation film. Moreover, such a spacer layer is highly hygroscopic and easy to be degraded over time.

### BRIEF DESCRIPTION OF THE DRAWINGS

FIG. 1 is a sectional view showing an example of a manufacturing method of a semiconductor device according to the present embodiment;

FIGS. 2A and 2B are sectional views showing the example of the manufacturing method of the semiconductor device, following to FIG. 1;

FIGS. 3A and 3B are sectional views showing the example of the manufacturing method of the semiconductor device, following to FIGS. 2A and 2B;

FIGS. 4A and 4B are sectional views showing the example of the manufacturing method of the semiconductor device, following to FIGS. 3A and 3B;

FIG. 5 is a flowchart showing an example of a film forming method of a spacer film according to the present embodiment;

FIG. 6 is a graph showing an analysis result of a spacer film 50 using Fourier transform infrared spectroscopy;

FIG. 7 is a graph showing an analysis result of a leakage current of the spacer film 50;

FIG. 8 is graph showing an analysis result of a withstand voltage of the spacer film 50;

FIG. 9 is graph showing a measurement result of capacity of the spacer film 50; and

FIG. 10 is graph showing change over time in OH groups contained the spacer film 50.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which TSVs are provided is assumed as “an upper direction”. Therefore, the term “upper direction” or “lower direction” occasionally differs from an upper direction or a lower direction based on a gravitational acceleration direction.

In a manufacturing method of a semiconductor device according to the present embodiment, a semiconductor substrate, which has a first face and a second face, is bonded to a support substrate with the first face facing toward the support substrate. The first face has a semiconductor element. The second face is located opposite to the first face. The semiconductor substrate is processed from the second face to form a contact hole to reach the first face from the second face. A first insulation film is formed on an inner surface of the contact hole. A metal is embedded on the first insulation film in the contact hole to form a metal electrode. The formation of the first insulation film is performed by plasma CVD in an atmosphere of 200° C. or lower, containing a gas containing silicon and oxygen, an oxygen-containing gas, and an NH-group containing gas.

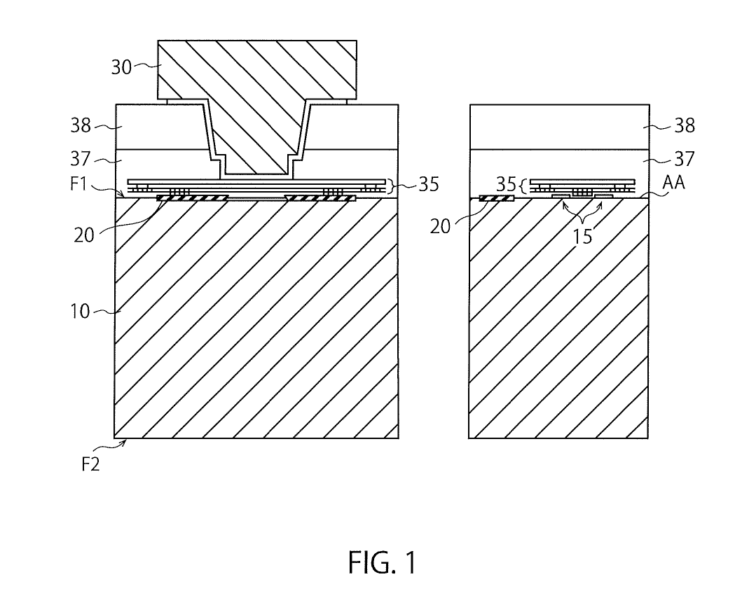

FIGS. 1 to 4B are sectional views showing an example of a manufacturing method of a semiconductor device according to the present embodiment. The semiconductor device may, for example, be a semiconductor chip having a NAND EEPROM (Electrically Erasable and Programmable Read-Only Memory) and the like. Hereinafter, a method for forming a TSV 40 in a semiconductor wafer will mainly be explained.

First of all, as shown in FIG. 1, STIs 20 are formed on a first face F1 of a semiconductor substrate 10 to define an active area AA. In this stage, the semiconductor substrate 10 is a semiconductor wafer that is not cut into pieces yet, which is, for example, a silicon substrate (silicon wafer). The STIs 20 are, for example, a silicon oxide film.

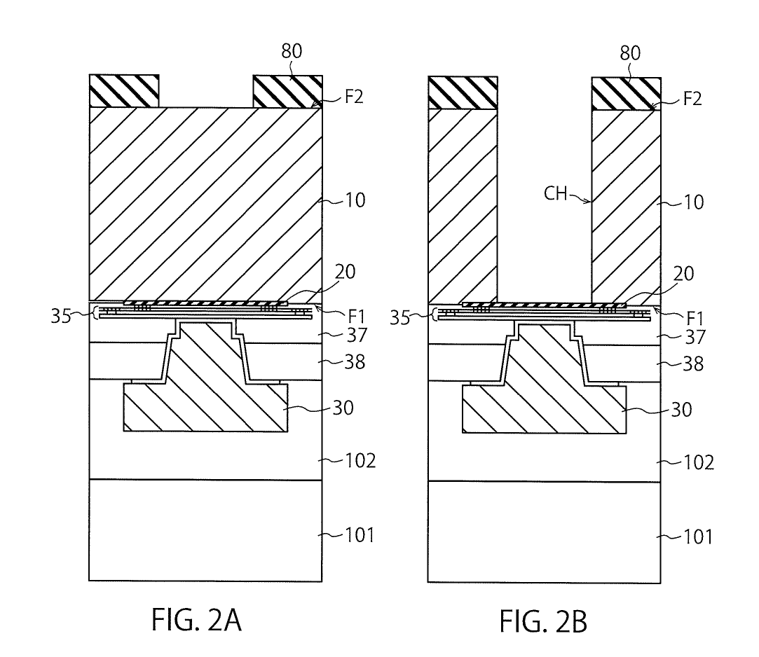

Subsequently, semiconductor elements 15 are formed in the active area AA. The semiconductor elements 15 may, for example, be a memory cell array, a transistor, a resistor or a capacitor. In the formation of the semiconductor elements 15, for example, a wiring structure 35 is formed on the STIs 20. The semiconductor elements 15 and the wiring structure 35 are covered with insulation films 37 and 38. Subsequently, a pad 30 is formed to be electrically connected to the wiring structure 35. The conductors 30 and 35 are formed on the STIs 120. FIG. 1 shows, not only a forming area of the TSV 40, but also a forming area of the semiconductor elements 15, whereas, in FIG. 2A and the following drawings, only the forming area of the TSV 40 is shown, with the forming area of the semiconductor device 15 being omitted.

Subsequently, as shown in FIG. 2A, the semiconductor substrate 10 is bonded on a support substrate 101 with an adhesive 102 so that a first face F1 of the semiconductor substrate 10 faces toward the support substrate 101. The adhesive 102 that bonds the semiconductor substrate 10 and the support substrate 101 may, for example, be an organic material that melts at a temperature exceeding about 200° C. A photoresist 80 is formed on a second face F2 of the semiconductor substrate 10 to be processed into a pattern of a contact hole CH for used in TSV. The second face F2 is a face of the semiconductor substrate 10, opposite to the first face F1.

Subsequently, as shown in FIG. 2B, the semiconductor substrate 10 is etched from the second face F2 using lithography and RIE (Reactive Ion Etching). In detail, using the photoresist 80 as a mask, the contact hole CH is formed from the second face F2 (rear face) opposite to the first face F1 having the semiconductor elements 15 formed thereon. The contact hole CH is formed so as to reach the first face F1 from the second face F2. In order to connect the TSV 40 to the wiring structure 35, the contact hole CH is formed in an area where the wiring structure 35 is present in an area of the STI 20. The STI 20 is exposed due to the formation of the contact hole CH.

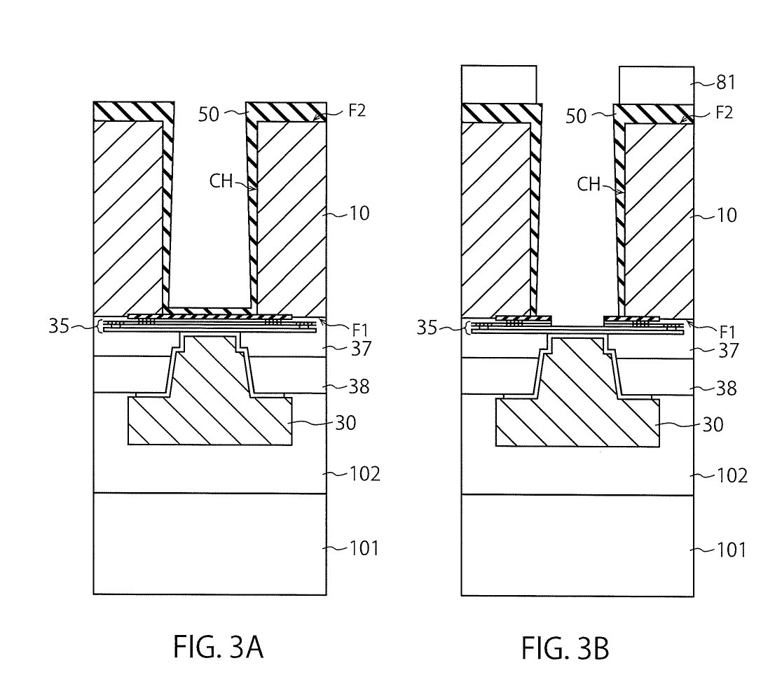

After the photoresist 80 is removed, as shown in FIG. 3A, a spacer film 50, as a first insulation film, is formed on the inner and bottom surfaces of the contact hole CH, and also on the second face F2 of the semiconductor substrate 10. The spacer film 50 is, for example, a silicon oxide film.

The contact hole CH used as the TSV 40 has a high aspect ratio. For example, the contact hole CH has a depth of about 28 μm with respect to its opening width of about 10 μm. In this case, the aspect ratio is 2.8. In the case of forming the spacer film 50 on the inner wall of the contact hole CH having such a high aspect ratio, a TEOS (TetraEthylOrthoSilicate) gas is often used as a source gas. This is because, an insulation film (for example, a silicon oxide film) formed with the TEOS gas has better coverage than an insulation film formed with a silane gas and a spacer film can also be formed on the bottom of the contact hole CH having a high aspect ratio. It is difficult for plasma CVD using the silane gas to form an insulation film enough up to the bottom of the contact hole CH because a thick insulation film is formed at the opening of the contact hole CH (having a large overhang). Therefore, in the present embodiment, with plasma CVD using the TEOS gas as a gas containing silicon and oxygen, the spacer film 50 is formed on the inner surface of the contact hole CH. The formation process of the spacer film 50 is performed, for example, in an atmosphere containing the TEOS gas, an oxygen-containing gas, and an NH-group-containing gas.

In the present embodiment, the semiconductor substrate 10 is bonded to the support substrate 101 with the adhesive 102 in the case where the semiconductor elements 15, the wiring layer 35, etc. are formed on the semiconductor substrate 10, and then, the contact hole CH, the spacer film 50, and the TSV 40 are formed from the second face F2 of the semiconductor substrate 10 (in the case of a via-last process). The adhesive 102 melts at a temperature exceeding about 200° C., not functioning as an adhesive. Therefore, the spacer film 50 is required to be formed in a low-temperature atmosphere of 200° C. or lower.

However, when the spacer film 50 is formed in an atmosphere of 200° C. or lower with plasma CVD using TEOS, a relatively large amount of OH groups (moisture) are taken in the spacer film 50. In this case, the spacer film 50 easily absorbs a lot of moisture in the atmosphere while it is left for a while. When the spacer film 50 is a silicon oxide film, the silicon oxide film that contains a lot of OH groups causes a larger leakage current, a lower withstand voltage, and a higher dielectric constant. When such a silicon oxide film is used as the spacer film 50, a large leakage current flows between the TSV 40 and the semiconductor substrate 10 to lower the withstand voltage therebetween. Moreover, as the dielectric constant of the spacer film 50 is higher, parasitic capacitance between the TSV 40 and the semiconductor substrate 10 increases, so that the semiconductor elements 15 may malfunction depending on the voltage applied to the TSV 40. It is therefore desirable to form a spacer film 50 having a small number of OH groups (moisture) in a low-temperature atmosphere of 200° C. or lower by plasma CVD using TEOS. It is preferable that the film forming temperature of the spacer film 50 is within a range of 100° C. to 200° C.

Accordingly, in the present embodiment, the spacer film 50 is formed using a process gas that is a combination of a TEOS gas and an oxygen-containing gas added with an NH-group-containing gas. The oxygen-containing gas may, for example, be NO₂, O₂, NO, etc. The NH-group-containing gas may be NH₃ or N₂ and the like.

The film forming conditions for the spacer film 50 are as follows. The follow rate of the TEOS gas to be supplied to a film forming chamber is, for example, about 1,500 mg/m. The follow rate of the oxygen-containing gas (for example, NO₂ gas) to be supplied to the film forming chamber is, for example, about 8,000 sccm. The follow rate of the NH-group-containing gas (for example, NH₃ gas) to be supplied to the film forming chamber is, for example, about 2,000 sccm. The film forming temperature is, for example, about 150° C. The film forming time is, for example, about 240 seconds. The partial pressure ratio among the TEOS gas, the oxygen-containing gas, and the NH-group-containing gas is about 1:1.5:6. The partial pressure of the NH-group-containing gas is comparatively lower than the partial pressures of the TEOS gas and the oxygen-containing gas

Under the film forming conditions described above, a silicon oxide film as the spacer film 50 is deposited inside the contact hole CH. NH groups are more easily taken in the silicon oxide film than the OH groups are, and hence are contained in the silicon oxide film, instead of the OH groups. The NH groups are connected to the dangling bonds in the silicon oxide film. In other words, the spacer film 50 contains a small amount of OH groups (moisture) but a large amount of NH groups.

The partial pressure ratio of the NH-group-containing gas is preferably 2 or smaller, or ⅓ or smaller of the pressure of O₂. This is because, when the partial pressure ratio of the NH-group-containing gas exceeds 2 or ⅓ of the pressure of O₂, the content of nitrogen contained in the silicon oxide film becomes larger and the dielectric constant increases. In other words, the silicon oxide film becomes like a silicon oxynitride film (SiON), a silicon nitride film, etc.

As described above, the spacer film 50 that contains a small amount of OH groups (moisture) can be formed by adding the NH-group-containing gas to the TEOS gas. Moreover, the spacer film 50 formed using the TEOS gas can cover the inner wall of the contact hole CH with excellent coverage.

Subsequently, as shown in FIG. 3B, the photoresist 80 is formed on the second face F2 except for the contact hole CH. Subsequently, using the photoresist 80 and the spacer film 50 as masks, the spacer film 50 on the bottom of the contact hole CH is removed by RIE (Reactive Ion Etching). In this way, the wiring layer 35 is exposed to the bottom of the contact hole CH.

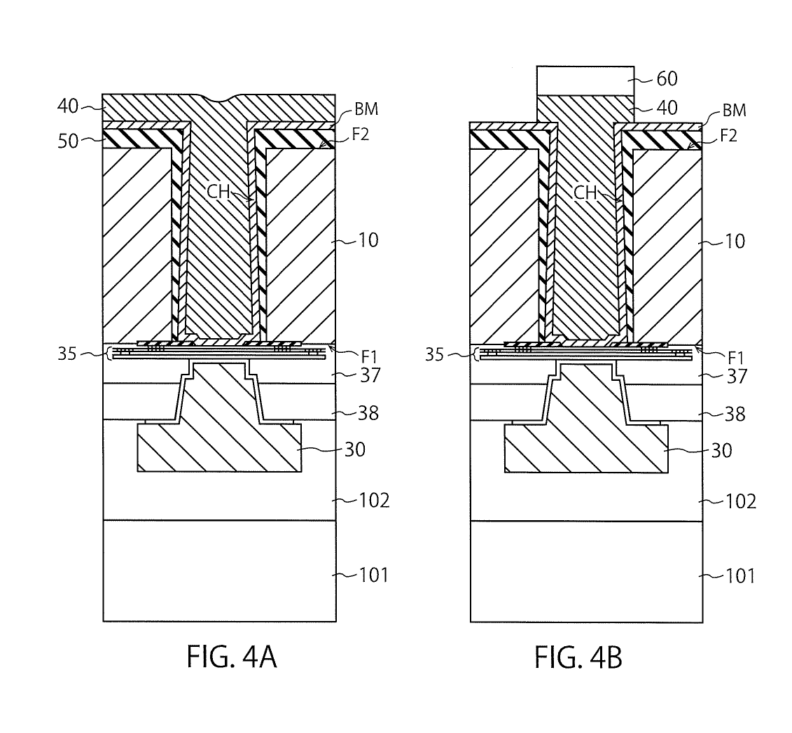

Subsequently, as shown in FIG. 4, a barrier metal BM is formed inside the contact hole CH and then a metal material of the TSV 40 is deposited therein. As the barrier metal BM, for example, Ti, Ta, or Ru, or a laminated film of these metals is used. As the TSV 40, for example, a metal material such as nickel is used. Accordingly, the metal material of the TSV 40 can be embedded in the contact hole CH to be electrically connected to the wiring layer 35. The TSV 40 can pull the wiring layer 35 on the first-face F1 side to the second-face F2 side.

Subsequently, using lithography and RIE, the TSV 40 and the barrier metal BM are processed to remove the materials of the TSV 40 and the barrier metal BM located on the field of the second face F2.

Subsequently, as shown in FIG. 4B, using plating or the like, a bump 60 is formed on the TSV 40. For the bump 60, for example, tin or the like is used. In this way, the semiconductor device according to the present embodiment is complete. Thereafter, the semiconductor device is cut into pieces of semiconductor chips. One semiconductor chip is laminated on another semiconductor chip and is electrically connected to still another semiconductor chip via the TSV 40, the bump 60, etc.

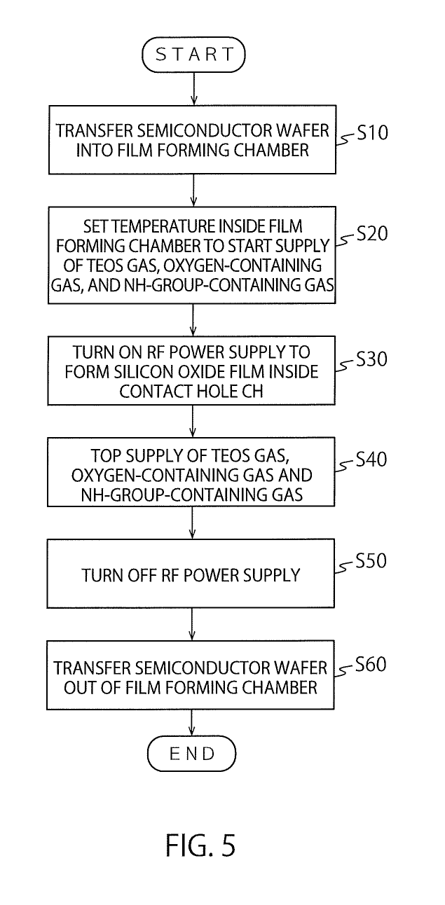

FIG. 5 is a flowchart showing an example of a film forming method of a spacer film according to the present embodiment. First of all, a semiconductor wafer formed with the contact hole CH is transferred into a film forming chamber of a plasma CVD apparatus (not shown) (S10). Subsequently, under the film forming conditions described above, the temperature inside the film forming chamber is set to start the supply of the TEOS gas, the oxygen-containing gas, and the NH-group-containing gas to the film forming chamber (S20).

Subsequently, an RF power supply is turned on to form a silicon oxide film as the spacer film 50 inside the contact hole CH by plasma CVD (S30).

Subsequently, the supply of the TEOS gas stops and also the supply of the oxygen-containing gas and the NH-group-containing gas stops (S40). Furthermore, the RF power supply is turned off (S50).

Thereafter, the semiconductor wafer is transferred out of the film forming chamber to end a film forming process (S60).

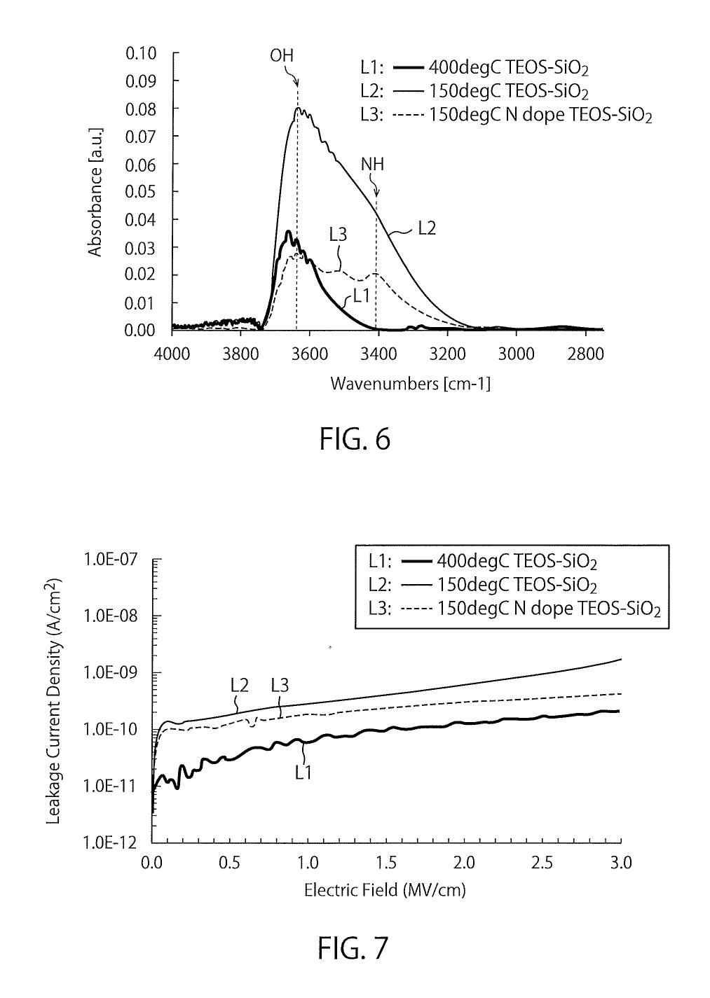

FIG. 6 is a graph showing an analysis result of the spacer film 50 using Fourier transform infrared spectroscopy (FT-IR). The abscissa indicates a wave number (cm⁻¹) per unit of length of infrared rays emitted to the spacer film 50. The ordinate indicates absorbance of the infrared rays. A line L1 indicates an analysis result of a silicon oxide film formed, using a TEOS gas with no NH-group-containing gas being added, in an atmosphere of 400° C. A line L2 indicates an analysis result of a silicon oxide film formed, using a TEOS gas with no NH-group-containing gas being added, in an atmosphere of 150° C. A line L3 indicates an analysis result of a silicon oxide film formed, using a TEOS gas with a NH-group-containing gas being added, in the atmosphere of 150° C. In other words, the line L3 indicates an analysis result of the spacer film 50 formed by the film forming method according to the present embodiment.

Referring to the line L1, it is found out that an OH-group peak is comparatively low, so that the spacer film 50 contains a comparatively small amount of OH groups. However, when the film forming process is performed at a temperature of 400° C., the adhesive 102 is melted, as described. Therefore, the film forming conditions corresponding to the line L1 cannot be practically adopted.

Referring to the line L2, it is found out that the OH-group peak is high, so that the spacer film 50 contains a large amount of OH groups. When the film forming process is performed at a low temperature of 150° C., using the TEOS gas with no NH-group-containing gas being added, the amount of OH groups contained in the spacer film 50 is very large.

Referring to the line L3, it is found out that the OH-group peak is low, with an NH-group peak appearing. In other words, it is found out that the spacer film 50 contains a small amount of OH groups but, instead, contains a large amount of NH groups. Even at a low temperature of 150° C., the amount of OH groups contained in the spacer film 50 can be restricted to a lower amount as long as the film forming process is performed using the TEOS gas with the NH-group-containing gas being added.

FIG. 7 is a graph showing an analysis result of a leakage current of the spacer film 50. The abscissa indicates the magnitude of an electric field applied to the spacer film 50. The ordinate indicates the leakage current. The lines L1 to L3 in FIGS. 7 to 9 correspond to the lines L1 to L3 in FIG. 6, respectively.

The spacer film shown by the line L1 has a comparatively small amount of OH groups and hence its leakage current is comparatively small. However, as described above, since the film forming process was performed at the temperature of 400° C., the film forming conditions corresponding to the line L1 cannot be adopted. The spacer film shown by the line L2 has a large amount of OH groups and hence its leakage current is large. In the spacer film 50 according to the present embodiment and shown by the line L3, the OH groups are replaced with the NH groups, so that, although the leakage current shown by the line L3 is larger than the leakage current of the line L1, it is clearly smaller than the leakage current of the line L2.

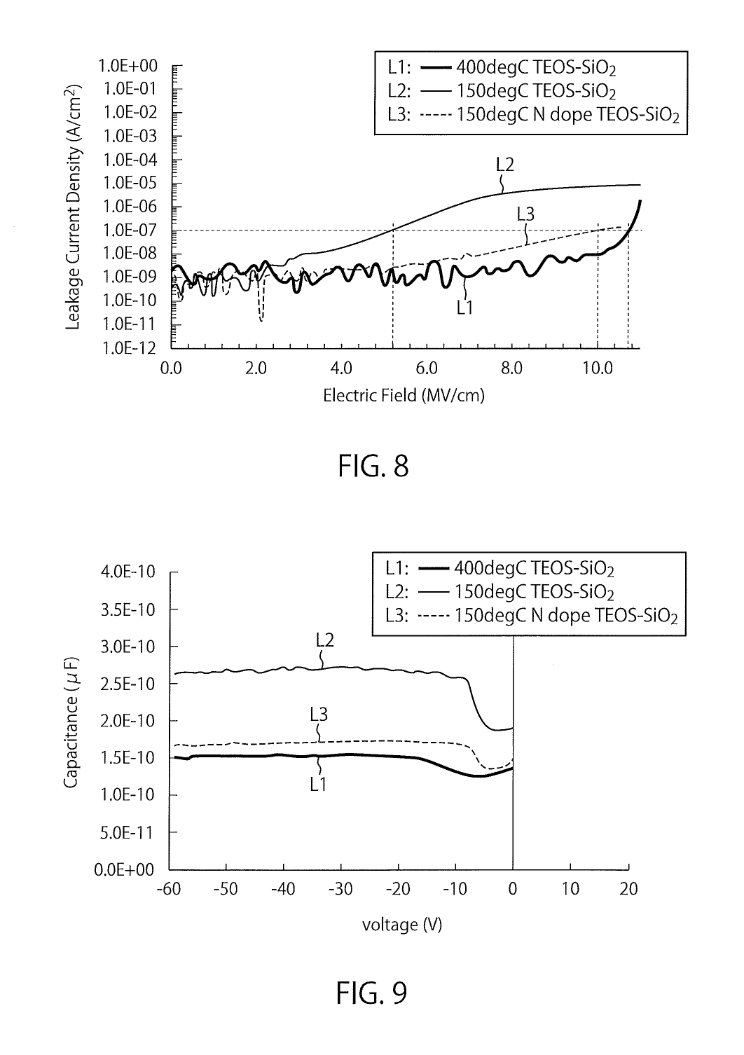

FIG. 8 is graph showing an analysis result of a withstand voltage of the spacer film 50. The abscissa indicates the magnitude of an electric field applied to the spacer film 50. The ordinate indicates a leakage current. An electric field with which the leakage current exceeds a predetermined value is defined as the withstand voltage.

The spacer film shown by a line L1 has a comparatively small amount of OH groups and hence the leakage current is small, so that the withstand voltage is comparatively high. However, as described above, since the film forming process was performed at the temperature of 400° C., the film forming conditions corresponding to the line L1 cannot be adopted. The spacer film shown by a line L2 has a large amount of OH groups and hence the leakage current is large, so that the withstand voltage is comparatively low. In the spacer film 50 according to the present embodiment and shown by a line L3, the OH groups are replaced with the NH groups, so that, although its withstand voltage is comparatively lower than the withstand voltage of the line L1, it is clearly higher than the withstand voltage of the line L2.

FIG. 9 is graph showing a measurement result of capacity of the spacer film 50. The abscissa indicates the magnitude of a voltage applied to the TSV 40. The ordinate indicates a capacitance value of the spacer film 50.

The spacer film shown by a line L1 has a comparatively small amount of OH groups and hence has a small capacitance value. However, as described above, the film forming process was performed at the temperature of 400° C., the film forming conditions corresponding to the line L1 cannot be adopted. The spacer film shown by a line L2 has a large amount of OH groups and hence has a large capacitance value. In this case, the TSV 40 and the semiconductor substrate 10 are coupled in capacitive coupling, so that the voltage applied to the TSV 40 may affect the semiconductor elements 15. On the contrary, in the spacer film 50 according to the present embodiment and shown by a line L3, the OH groups are replaced with the NH groups, so that, although the capacitance value of the line L3 is little bit larger than the capacitance value of the line L1, it is clearly smaller than the capacitance value of the line L2. Along with this, the semiconductor device according to the present embodiment hardly causes hysteresis on the spacer film 50.

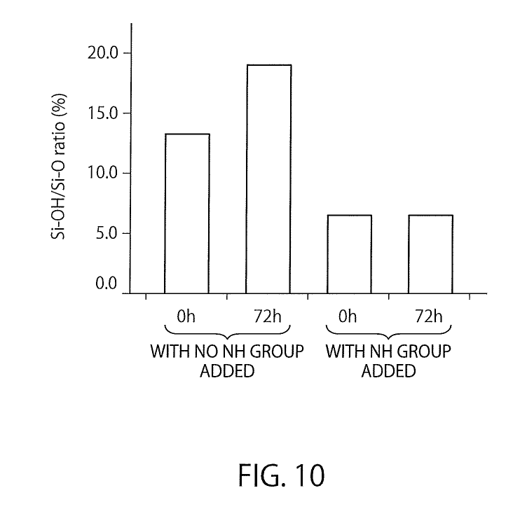

FIG. 10 is a graph showing change over time in the OH groups contained the spacer film 50. In this experiment, with the moment just after film formation being zero hour (Oh), the content of the OH groups after 72 hours (72 h) was measured. The ordinate indicates a content ratio of SiOH to SiO. The spacer film 50 (with no NH groups being added) formed without addition of the NH-group-containing gas already has a high OH-group content ratio just after film formation. The OH-group content ratio of the spacer film 50 is further higher after the spacer film 50 was left for 72 hours. By contrast, the spacer film 50 (with the NH groups being added) formed with addition of the NH-group-containing gas has a low OH-group content ratio just after film formation. Moreover, the OH-group content ratio of this spacer film 50 is almost unchanged to remain low even after the spacer film 50 was left for 72 hours. As described, because of the addition of the NH-group-containing gas, the OH-group content ratio of the spacer film 50 is, not only lowered, but also not increased over time. Accordingly, the degradation of the spacer film 50 over time can be restricted. In other words, because of the addition of the NH-group-containing gas, the leakage-current characteristics, the withstand-voltage characteristics, and the capacitance characteristics of the spacer film 50 can be improved and an excellent state can be maintained overtime.

As described above, in the manufacturing method of the semiconductor device according to the present embodiment, using the TEOS gas, the spacer film 50 can be formed with excellent coverage at low temperatures. Moreover, since the OH groups (moisture) contained in the spacer film 50 can be restricted, the leakage current and cracks of the spacer film 50 can be restricted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of a semiconductor device, comprising:
bonding a semiconductor substrate, which has a first face and a second face, to a support substrate with the first face facing toward the support substrate, the first face having a semiconductor element, and the second face being located opposite to the first face;
processing the semiconductor substrate from the second face to form a contact hole reaching the first face from the second face;
forming a first insulation film on an inner surface of the contact hole; and
embedding a metal on the first insulation film in the contact hole to form a metal electrode,
wherein the formation of the first insulation film is performed by plasma CVD (Chemical Vapor Deposition) in an atmosphere of 200° C. or lower, containing a gas containing silicon and oxygen, an oxygen-containing gas, and an NH-group containing gas.

2. The manufacturing method of the semiconductor device according to claim 1, wherein
the gas containing silicon and oxygen is a TEOS (TetraEthylOrthoSilicate) gas,
the oxygen-containing gas is NO₂ or O₂, and
the NH-group containing gas is NH₃ or N₂.

3. The manufacturing method of the semiconductor device according to claim 1, wherein the formation of the first insulation film is performed in an atmosphere of 200° C. or lower.

4. The manufacturing method of the semiconductor device according to claim 2, wherein the formation of the first insulation film is performed in an atmosphere of 200° C. or lower.

5. The manufacturing method of the semiconductor device according to claim 3, wherein the formation of the first insulation film is performed in an atmosphere of 100° C. to 200° C.

6. The manufacturing method of the semiconductor device according to claim 4, wherein the formation of the first insulation film is performed in an atmosphere of 100° C. to 200° C.

7. The manufacturing method of the semiconductor device according to claim 1, wherein an NH group is connected to a dangling bond of the first insulation film.

8. The manufacturing method of the semiconductor device according to claim 2, wherein an NH group is connected to a dangling bond of the first insulation film.

9. The manufacturing method of the semiconductor device according to claim 3, wherein an NH group is connected to a dangling bond of the first insulation film.

10. The manufacturing method of the semiconductor device according to claim 1, wherein the contact hole, the first insulation film, and the metal electrode are formed after the semiconductor element and a wiring layer are formed on the first face of the support substrate.

11. The manufacturing method of the semiconductor device according to claim 2, wherein the contact hole, the first insulation film, and the metal electrode are formed after the semiconductor element and a wiring layer are formed on the first face of the support substrate.

12. The manufacturing method of the semiconductor device according to claim 3, wherein the contact hole, the first insulation film, and the metal electrode are formed after the semiconductor element and a wiring layer are formed on the first face of the support substrate.

13. The manufacturing method of the semiconductor device according to claim 7, wherein the contact hole, the first insulation film, and the metal electrode are formed after the semiconductor element and a wiring layer are formed on the first face of the support substrate.

14. The manufacturing method of the semiconductor device according to claim 1, wherein the formation of the first insulation film comprises:
depositing a first insulation film on an inner surface of and a bottom surface of the contact hole, and on the second face of the semiconductor substrate;
forming a mask material on the first insulation film located on the second face; and
etching the first insulation film located on the bottom surface of the contact hole using the mask material and the first insulation film as masks, and thereafter, forming a metal electrode in the contact hole.

15. The manufacturing method of the semiconductor device according to claim 1, wherein in the atmosphere of forming the first insulation film, a partial pressure of the NH-group-containing gas is comparatively lower than a partial pressure of the gas containing silicon and oxygen, and a partial pressure of the oxygen-containing gas.

16. The manufacturing method of the semiconductor device according to claim 2, wherein in the atmosphere of forming the first insulation film, a partial pressure of the NH-group-containing gas is comparatively lower than a partial pressure of the gas containing silicon and oxygen, and a partial pressure of the oxygen-containing gas.

17. The manufacturing method of the semiconductor device according to claim 3, wherein in the atmosphere of forming the first insulation film, a partial pressure of the NH-group-containing gas is comparatively lower than a partial pressure of the gas containing silicon and oxygen, and a partial pressure of the oxygen-containing gas.
